(19) United States
(12) Patent Application Publication
(10) Pub. No.: US 2017/0214266 A1
(43) Pub. Date: Jul. 27, 2017

(54) ELECTRIC POWER STORAGE DEVICE, CONTROL DEVICE, ELECTRIC POWER STORAGE SYSTEM, METHOD FOR CONTROLLING ELECTRIC POWER STORAGE DEVICE, AND NON-TRANSITORY COMPUTER-READABLE MEDIUM STORING CONTROL PROGRAM

(71) Applicant: NEC Corporation, Tokyo (JP)

(72) Inventors: Shingo TAKAHASHI, Tokyo (JP); Junichi MIYAMOTO, Tokyo (JP); Yuichi IMAMURA, Tokyo (JP); Sho OHTANI, Tokyo (JP)

(73) Assignee: NEC Corporation, Tokyo (JP)

(21) Appl. No.: 15/515,066

(22) PCT Filed: Sep. 18, 2015
(86) PCT No.: PCT/JP2015/004791

§ 371 Date: Mar. 28, 2017

(30) Foreign Application Priority Data
Sep. 29, 2014 (JP) 2014-197744

(51) Int. Cl. H02J 7/00; G01R 31/36

(52) U.S. Cl. CPC H02J 7/0068; H02J 7/007; G01R 31/3679

(57) ABSTRACT

A control device for measuring the capacity of a lithium ion secondary battery without inconveniencing the user of the secondary battery, wherein the control device controls operations for a plurality of charge and discharge cycles comprising charging of the secondary battery and discharging of the secondary battery following thereafter. The control device acquires a first voltage which indicates the maximum voltage value in a first charge/discharge cycle, a discharge end voltage which indicates a voltage in the period between the end of discharge in the first charge/discharge cycle and the start of the next charge, and a reference voltage which indicates a voltage at which capacity measurement of the secondary battery is started. When the discharge end voltage is higher than the reference voltage, a second voltage which indicates the maximum voltage value in a second charge/discharge cycle, which is the next cycle after the first charge/discharge cycle, is set lower than the first voltage.

### TECHNICAL FIELD

The present invention relates to an electric power storage device, a control device, an electric power storage system, a method for controlling an electric power storage device, and a non-transitory computer-readable medium storing a control program.

### BACKGROUND ART

There is a technology of estimating a full charge capacity of a lithium ion secondary battery by use of initial characteristics of an open circuit voltage (OCV) of the battery and a stage of charge (SOC) of the battery (PATENT LITERATURE 1).

However, a lithium ion secondary battery degrades by repeated charging and discharging, and influence of a storage temperature. As degradation of a lithium ion secondary battery progresses, difference between an estimated full charge capacity and an actual full charge capacity gradually becomes greater. Consequently, there is a risk that required electric power may not be charged or discharged. Accordingly, it is important to measure a full charge capacity of the battery after degradation.

For example, PATENT LITERATUREs 2 and 3 describe technologies of measuring a full charge capacity of a secondary battery. In PATENT LITERATURE 2, a storage capacity of a lithium ion secondary battery is measured by integrating an amount of charge-discharge current between a time when a lithium ion secondary battery enters a fully discharged state and a time when the battery enters a fully charged state. Alternatively, the storage capacity is estimated by integrating charge-discharge current between a time when the battery enters a fully charged state and a time when the battery enters a fully discharged state. Meanwhile, a user of a lithium ion secondary battery discharges required electric power out of electric power stored in the lithium ion secondary battery. Further, the user charges the lithium ion secondary battery so as to secure required electric power. For example, a user sets a time period in which electric power demand of a load is low, a time period in which a power purchase price is low, and the like as a charging period. A lithium ion secondary battery is charged in every set charging period. Alternatively, a user may frequently charge a lithium ion secondary battery so as to maintain a certain amount of charge energy. Accordingly, when a lithium ion secondary battery is charged and discharged in accordance with a user request, the lithium ion secondary battery is not necessarily in a fully discharged state or a fully charged state within a predetermined period. Further, depending on a specification of a lithium ion secondary battery, it may take so much time to bring the battery in a fully discharged state or a fully charged state that use is hindered. In other words, full charge capacity measurement may not be started when a fully charged state is set as a reference point for starting the full charge capacity measurement. Further, full charge capacity measurement may not be ended when a fully discharged state is set as a reference point for ending the full charge capacity measurement.

Accordingly, in PATENT LITERATURE 3, an integrated current value in a period between a time point when a reference point set in a range from 15 to 95% of a charge capacity is detected and a time point when a full charge voltage is reached is measured. Further, from a table associating a reference point with a battery capacity, a battery capacity corresponding to a charge capacity from zero to the reference point is acquired. By adding the acquired battery capacity to the integrated current value, a full charge capacity of a lithium ion secondary battery is measured.

### CITATION LIST

### Patent Literature

[Patent Literature 1] Japanese Patent Application Publication No. 2010-196641

[Published patent application 2] Japanese Patent Application Publication No. 2013-347045

[Published patent application 3] Japanese Patent Application Publication No. 2012-145403

### SUMMARY OF INVENTION

### Technical Problem

In PATENT LITERATURE 3, a lithium ion secondary battery is discharged until the battery reaches a state in which voltage of the battery is lower than an inflection point being a reference point, in a time period in which a load device is not operated, such as nighttime. Then, the secondary battery is charged by electric power supplied by a commercial power source, and a full charge capacity is measured. Accordingly, discharging not requested by a user of the lithium ion secondary battery is performed in order to measure the full charge capacity.

An object of the present invention is to provide an electric power storage device, a control device, a method for controlling an electric power storage device, and a control program for an electric power storage device that perform capacity measurement without hampering convenience of a user of a lithium ion secondary battery.

### Solution to Problem

A control device of the present invention is a control device for controlling an operation of a plurality of charge-discharge cycles including charging of a secondary battery and discharging immediately following the charging, the control device acquires a first voltage representing a highest voltage value in a first of the charge-discharge cycles, a discharge end voltage representing a voltage in a period from an end of discharging to a next start of charging in the first charge-discharge cycle, and a reference voltage representing a voltage at which capacity measurement of a secondary battery is started; and, when the discharge end voltage is higher than the reference voltage, the control device sets a second voltage representing a highest voltage value in a second charge-discharge cycle following the first charge-discharge cycle to a voltage lower than the first voltage.

An electric power storage system of the present invention comprises: an electric power storage device including a battery module including one or more secondary batteries, and a control device controlling charging and discharging of the battery module, and a load and an electric power supply source connected to the electric power storage device, wherein the control device acquires a first voltage representing a highest voltage value in a first charge-discharge cycle including charging and discharging immediately following the charging, a discharge end voltage representing a voltage in a period other than charging and discharging in the first charge-discharge cycle, and at the same time a voltage in a period from an end of discharging to a next start of discharging, and a reference voltage representing a voltage at which capacity measurement is started, and the control device charges the battery module up to a second voltage lower than the first voltage when the discharge end voltage is higher than the reference voltage.

A method for controlling an electric power storage device of the present invention is a method for controlling an electric power storage device that includes a battery module including one or more secondary batteries, and a control device controlling charging and discharging of the battery module, the method comprises: acquiring a first voltage representing a highest voltage value in a first charge-discharge cycle including charging and discharging immediately following the charging, a discharge end voltage representing a voltage in a period other than charging and discharging in the first charge-discharge cycle, and at the same time a voltage in a period from an end of discharging to a next start of discharging, and a reference voltage representing a voltage at which capacity measurement is started; and, when the discharge end voltage is higher than the reference voltage, setting a second voltage representing a highest voltage value in a second charge-discharge cycle representing a charge-discharge cycle following the first charge-discharge cycle to a voltage lower than the first voltage.

A non-transitory computer-readable medium stores a control program of a control device for controlling an operation of a plurality of charge-discharge cycles including charging of a secondary battery and discharging immediately following the charging, the control program causes a computer to perform: processing of acquiring a first voltage representing a highest voltage value in a first of the charge-discharge cycles; and processing of setting a second voltage representing a highest voltage value in a second charge-discharge cycle following the first charge-discharge cycle to a voltage lower than the first voltage, when a discharge end voltage representing a voltage in a period from an end of discharging to a next start of charging in the first charge-discharge cycle is lower than a reference voltage representing a voltage at which capacity measurement is started.

A control device of the present invention comprises: a measurement unit measuring a voltage of a battery module including one or more lithium ion secondary batteries; a capacity measurement unit measuring a battery capacity of the battery module; a control unit acquiring a first voltage representing a highest voltage value in a first charge-discharge cycle including charging and discharging immediately following the charging, and a capacity measurement permission signal instructing capacity measurement, and setting a second voltage representing a highest voltage value in a second charge-discharge cycle representing a charge-discharge cycle following the first charge-discharge cycle to a voltage lower than the first voltage; and a charge-discharge unit charging the battery module up to a second voltage.

### Advantageous Effect of Invention

The present invention is able to provide an electric power storage device, a control device, a method for controlling an electric power storage device, and a control program for an electric power storage device that are able to measure a battery capacity of a lithium ion secondary battery while securing convenience of the electric power storage device.

### BRIEF DESCRIPTION OF DRAWINGS

FIG. 1 is a diagram illustrating an example of a functional block of an electric power storage device according to the present exemplary embodiment.

FIG. 2 is a diagram illustrating an example of a characteristic curve (open terminal voltage curve) illustrating a voltage (V) versus an SOC (%) of a lithium ion secondary battery, according to the present exemplary embodiment.

FIG. 3 is a flowchart illustrating an example of an operation of a control device according to the present exemplary embodiment.

FIG. 4 is a diagram illustrating an example of temporal change of a voltage in the electric power storage device according to the present exemplary embodiment.

FIG. 5 is a diagram illustrating an example of a display unit in an electric power storage device according to the present exemplary embodiment.

FIG. 6 is a flowchart illustrating an example of an operation of a control device according to the present exemplary embodiment.

FIG. 7 is a diagram illustrating an example of temporal change of a voltage in the electric power storage device according to the present exemplary embodiment.

FIG. 8 is a flowchart illustrating an example of an operation of a control device according to the present exemplary embodiment.

FIG. 9 is a diagram illustrating an example of temporal change of a voltage in an electric power storage device according to the present exemplary embodiment.

FIG. 10 is a flowchart illustrating an example of an operation of a control device according to the present exemplary embodiment.

FIG. 11 is a diagram illustrating an example of temporal change of a voltage in an electric power storage device according to the present exemplary embodiment.

FIG. 12 is a diagram illustrating an example of a configuration of an electric power storage system.

FIG. 13 is a diagram illustrating a modified example of the configuration of the electric power storage system.

### DESCRIPTION OF EMBODIMENTS

Electric power storage devices according to exemplary embodiments of the present invention will be described in detail below in accordance with the drawings.

### First Exemplary Embodiment

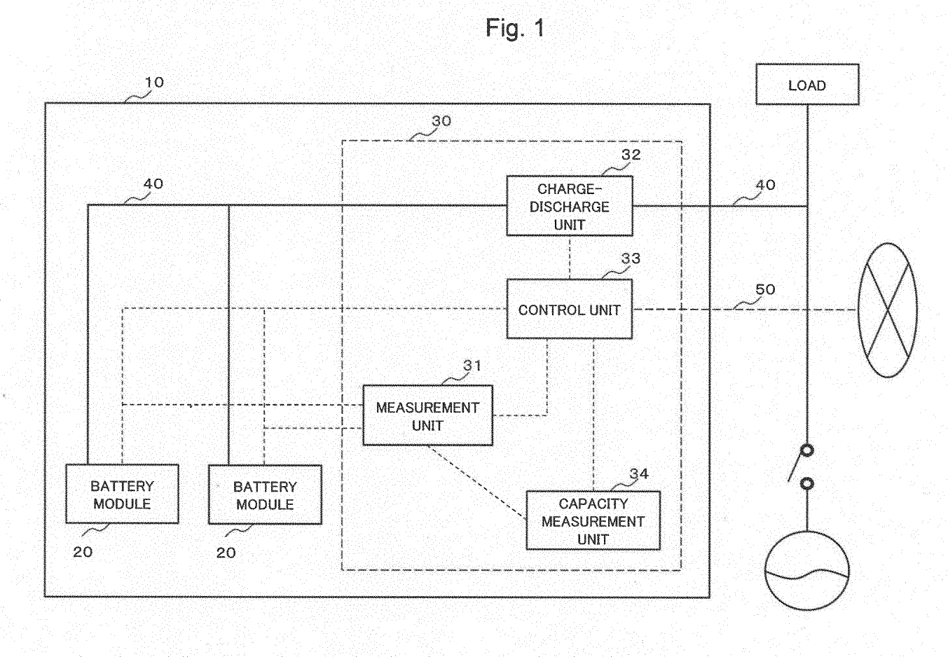

FIG. 1 illustrates an example of a functional block diagram of an electric power storage device 10 according to the present exemplary embodiment. The electric power storage device 10 according to the present exemplary embodiment includes a battery module 20 storing or releasing electric power, and a control device 30. The battery module 20 is connected to the control device 30 by an electric power line 40. The control device 30 is connected by the electric power line 40 to a distribution system including a load consuming electric power, and an electric power supply source supplying electric power. In other words, the battery module 20 is connected to the distribution system through the control device 30, discharges to the distribution system, and charges from the distribution system. Further, the control device 30 may be connected to a network by a communication line 50 to transmit and receive information to and from outside.

The battery module 20 includes a lithium ion secondary battery capable of storing and releasing electric power. The battery module 20 may include one lithium ion secondary battery (cell). Alternatively, the battery module 20 may include an assembled battery connecting cells in series or in parallel. Additionally, the battery module 20 may include a plurality of assembled batteries connected in series or in parallel.

The electric power supply source supplies electric power to the electric power storage device 10. The electric power supply source is a device generating electric power by use of thermal energy, kinetic energy, or chemical energy, and supplying electric power to the load and the electric power storage device 10. The electric power supply source may be a power plant or the like owned by an electric power company or the like, or a distributed power source owned and managed by an electric power consumer using electric power.

The load is an apparatus, equipment, and a facility, consuming electric power. For example, the load includes electric apparatuses such as air conditioning, lighting, and a computer. The load according to the present exemplary embodiment is connected to the electric power storage device 10, and is supplied with electric power by the electric power storage device 10.

The control device 30 includes a measurement unit 31 measuring a voltage of the battery module 20, a charge-discharge unit 32 enabling connection between the battery module 20 and the distribution system, a control unit 33 instructing charging and discharging of the battery module 20 to the charge-discharge unit 32, and a capacity measurement unit 34 measuring a battery capacity of the battery module 20.

The measurement unit 31 is connected to both terminals of the lithium ion secondary battery and measures a voltage of the battery module 20. Further, the measurement unit 31 measures a discharge current from the battery module 20 and a charge current to the battery module 20. When the battery module is an assembled battery connecting a plurality of lithium ion secondary batteries in parallel, the plurality of lithium ion secondary batteries connected in parallel are treated as one cell, and a voltage across the cell is measured. When the battery module is an assembled battery connecting a plurality of lithium ion secondary batteries in series, each lithium ion secondary battery is treated as one cell, and a voltage across each cell is measured. For example, it is assumed that there is an assembled battery composed of four cells in parallel and eight cells in series, totaling 32 cells. In this case, cells connected in parallel are treated as one cell so that it is assumed that there are eight cells connected in series, and voltage measurement of eight cells is performed.

Furthermore, a state of charge (SOC), a depth of discharge (DOD), a remaining chargeable capacity, and a remaining dischargeable capacity may be calculated by use of a measured voltage and a measured current. The remaining chargeable capacity is chargeable energy and the remaining dischargeable capacity is dischargeable energy, and a sum of the remaining chargeable capacity and the remaining dischargeable capacity is a storage capacity.

The measurement unit 31 transmits a measured voltage, a measured current, an SOC, and a DOD to the control unit 33. Additionally, the measurement unit 31 transmits the measured voltage and the measured current to the capacity measurement unit 34.

The charge-discharge unit 32 charges and discharges the battery module 20 in accordance with an instruction from the control unit 33. By connecting the distribution system and the battery module 20, the charge-discharge unit 32 discharges electric power stored by the battery module 20 and charges the battery module 20 with electric power. Further, the charge-discharge unit 32 converts AC power supplied from the distribution system into DC current and converts DC power discharged by the battery module 20 into AC current.

For example, when receiving a charge start instruction from the control unit 33, the charge-discharge unit 32 connects the battery module 20 and the electric power supply source. When receiving a charge end instruction from the control unit 33, the charge-discharge unit 32 interrupts connection between the battery module 20 and the electric power supply source. When receiving a discharge instruction from the control unit 33, the charge-discharge unit 32 connects the battery module 20 and the load. On the other hand, when receiving a discharge end instruction from the control unit 33, the charge-discharge unit 32 interrupts connection between the battery module 20 and the load.

There may be a case that an anomaly occurs in the battery module 20 or the distribution system, and charging and discharging cannot be securely performed. In this case, the charge-discharge unit 32 may suspend charging and discharging without an instruction from the control unit 33. The charge-discharge unit 32 may previously hold a condition for suspending charging and discharging.

The control unit 33 may acquire a charge instruction and a discharge instruction from an external server or the like through the network. Alternatively, the control unit 33 may previously hold a charge-discharge schedule previously indicating a period and a date and time when charging and discharging are performed, and outputs thereof. The control unit 33 may instruct charging and discharging to the charge-discharge unit 32, in accordance with the acquired charge instruction and the acquired discharge instruction.

By use of a voltage acquired from the measurement unit 31, the control unit 33 determines whether or not capacity measurement measuring a battery capacity can be started. The control unit 33 acquires a discharge end voltage representing a voltage in a period from an end of discharging to a next start of charging in a charge-discharge cycle including charging and discharging immediately following the charging, and a reference voltage representing a voltage at which capacity measurement is started. The control unit 33 compares the acquired discharge end voltage with the acquired reference voltage. When the discharge end voltage is lower than the reference voltage, the control unit 33 determines that capacity measurement can be started. When determining that capacity measurement can be started, the control unit 33 instructs the charge unit 32 to charge the battery module 20 up to a capacity measurement ending voltage.

The charge-discharge cycle is a period including charging and discharging immediately following the charging. The charge-discharge cycle is a period from a start of charging to a next start of charging with discharging placed in between. In a case of consecutive charging processes such as charge-charge, the consecutive charging processes may be treated as one charging process. Similarly in a case of consecutive discharging processes, the consecutive discharging processes may be treated as one discharging process. Further, a waiting period without charging or discharging may be included between charging and discharging.

The discharge end voltage represents a voltage in a period other than discharging and charging, and at the same time a voltage in a period from an end of discharging to a next start of charging. The end of discharging is different from a voltage of the battery module 20 reaching a discharge termination voltage being a voltage for secure discharging avoiding overdischarge, or reaching a fully discharged state corresponding to a stage of charge of 0%. The end of discharging simply indicates that electric power supply from the battery module 20 to the distribution system ends. For example, the control unit 33 may determine an end of discharging by an end of a discharge mode. Discharging and charging indicate electric power demand and supply from and to the battery module 20 and the distribution system. Self-discharging of a lithium ion secondary battery is not included in discharging. The discharge end voltage may be a voltage at a certain point in a period from an end of discharging to a next start of charging, or may be a mean voltage value in a period from an end of discharging to a next start of charging. Alternatively, a voltage at a time of the charge-discharge unit 32 receiving a discharge end instruction, or a voltage in a state that the charge-discharge unit 32 is not connected to the distribution system after discharging may be acquired.

As another example, the electric power storage device 10 may set a period in which the battery module 20 is charged (charging period). In this case, the lowest voltage of a voltage at a starting point of a predetermined charging period and a voltage in a dischargeable period representing a period other than a charging period may be set as the discharge end voltage. The method of setting a charging period is not particularly limited. For example, a period in which a power purchase price of electric power supplied by the electric power supply source is low or a period in which electric power demand of the load is low may be preset as a charging period, or a charging period may be started by a charge start signal from outside.

The reference voltage represents a voltage at which capacity measurement is started. For example, a voltage in a fully discharged state or a discharge termination voltage may be used. Alternatively, the reference voltage may be a voltage set correspondingly to a characteristic of a lithium ion secondary battery. However, a voltage close to the fully discharged state (a stage of charge of 0%) is preferable. Setting a voltage close to full discharge as a reference voltage facilitates calculation of a battery capacity from the fully discharged state to the reference voltage. The fully discharged state represents a state in which a stage of charge of the battery module 20 reaches 0%. Further, the fully discharged state is also defined by a voltage of a cell constituting the battery module 20. A state in which a voltage of a cell constituting the battery module 20 reaches a lower voltage limit of a preset operating range may be determined as the fully discharged state.

The timing to determine whether or not capacity measurement can be started is not particularly limited. For example, the control unit 33 may previously hold a capacity measurement start schedule. For example, the control unit 33 may hold a capacity measurement start schedule by which whether or not capacity measurement can be started is determined at a specific date and time. Alternatively, the control unit 33 may start capacity measurement when a gap between an estimated battery capacity and an actual battery capacity occurs, or when an instructed amount of energy cannot be discharged.

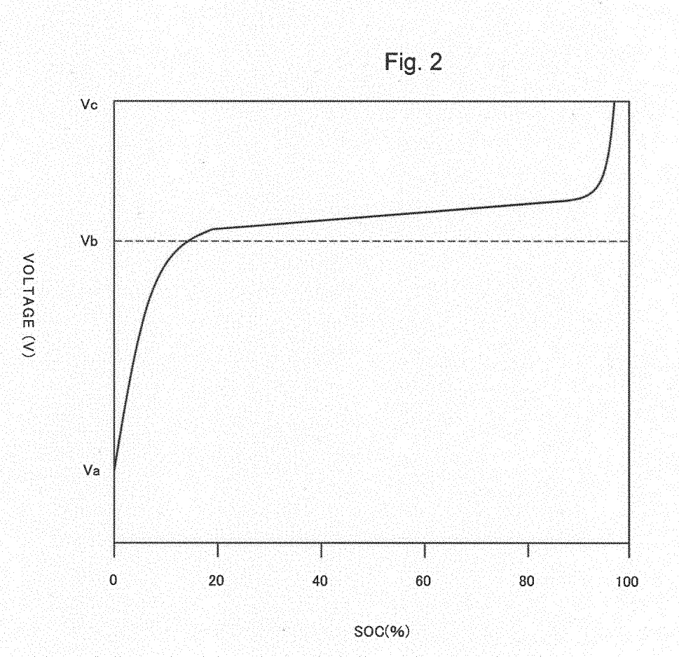

An example of the reference voltage is illustrated by use of FIG. 2. FIG. 2 is a diagram illustrating an example of a characteristic curve (open terminal voltage curve) illustrating a voltage (V) versus an SOC (%) of a lithium ion secondary battery. For example, when a battery voltage becomes Va in this example, a stage of charge becomes 0% representing a fully discharged state. Further, in the open terminal voltage curve, a slope of the voltage V greatly changes in an SOC range from 0 to 20% and in an SOC range from 90 to 100%. In a case of a lithium ion secondary battery having such a characteristic curve, a voltage Vb corresponding to an inflection part may be set as a reference voltage.

When a discharge end voltage is lower than or equal to the reference voltage, it is determined that capacity measurement can be performed. The control unit 33 instructs the charge-discharge unit 32 to charge the battery module 20 up to a capacity measurement ending voltage. Further, the control unit 33 instructs the capacity measurement unit 34 to start capacity measurement of the battery module 20.

The capacity measurement ending voltage is a voltage that ends capacity measurement. The capacity measurement voltage is a voltage higher than the reference voltage. The capacity measurement ending voltage is preferably a voltage in a fully charged state. The fully charged state represents a state in which the battery module 20 is charged to a stage of charge of 100%. Further, the fully charged state is also defined by a voltage of a cell constituting the battery module 20. A state in which a voltage of a cell constituting the battery module 20 reaches an upper voltage limit of a preset operating range may be determined as the fully charged state.

On the other hand, when the discharge end voltage is higher than the reference voltage, the control unit 33 determines that capacity measurement cannot be started. The discharge end voltage being higher than the reference voltage means that charge energy in the charge-discharge cycle is lower than supply energy to the load. Accordingly, a highest voltage value in a charge-discharge cycle is controlled. When the discharge end voltage in a first charge-discharge cycle is higher than the reference voltage, the control unit 33 acquires the highest voltage value (first voltage) in the first charge-discharge cycle. The control unit 33 determines a highest voltage value in a second charge-discharge cycle being a charge-discharge cycle following the first charge-discharge cycle. The control unit 33 determines the highest voltage value (second voltage) in the second charge-discharge cycle to be a value lower than the first voltage. Additionally, the control unit 33 instructs the charge-discharge unit 32 to charge the battery module 20 up to the second voltage.

The highest voltage value in a charge-discharge cycle represents a highest voltage value in a charge-discharge cycle including charging and discharging immediately following the charging. Alternatively, the highest voltage value may be a target voltage for charging instructed by the control unit 33 to the charge-discharge unit 32. Reaching a highest voltage value is different from a voltage of the battery module 20 reaching a charge termination voltage being a voltage for secure charging avoiding overcharge. Further, reaching a highest voltage value is different from reaching a fully charged state (a stage of charge of 100%). The highest voltage value simply represents a destination point of voltage when supplying electric power from the electric power supply source to the battery module 20. For example, a voltage at a time point when charging ends may be determined as the highest value. When charging the battery module 20 up to a full charge capacity, a full charge voltage becomes the highest voltage value, and, when charging the battery module 20 up to a stage of charge of 80%, a voltage at the stage of charge of 80% becomes the highest voltage value. In a period in which whether or not capacity measurement can be started is not determined, the electric power storage device 10 is charged up to a value corresponding to electric power demand of the load, or charge energy or a stage of charge requested by a user of the electric power storage device 10. A voltage at a time point of charge completion may be determined as the highest voltage value.

The method of the control unit 33 lowering a highest voltage value in a charge-discharge cycle is not particularly limited. The control unit 33 may divide a first voltage by a certain value, or multiply a first voltage by any value less than or equal to one. Alternatively, the control unit 33 may determine a second voltage by which future discharge energy estimated in accordance with a usage history of the electric power storage device 10, electric power demand of the load, and the like can be maintained. For example, a home energy management system (HEMS) or a watt meter calculates energy demand of a load and a user that receive electric power supply from the electric power storage device 10, and a predicted value thereof. The HEMS or the watt meter transmits the calculated energy demand and the calculated predicted value thereof to the control unit 33 through the network. The control unit 33 may determine a second voltage so that a charge capacity is lower than or equal to the acquired energy demand.

By setting a highest voltage value in a second charge-discharge cycle to a second voltage being a voltage lower than a first voltage, a remaining chargeable capacity of the electric power storage device 10 can be reduced. Accordingly, compared with a case that the electric power storage device 10 is charged up to the first voltage, the possibility of charge energy being lower than discharge energy to the load becomes higher. That is to say, the possibility of a discharge end voltage in a charge-discharge cycle being lower than or equal to a reference voltage becomes higher. Accordingly, the possibility of starting battery capacity measurement becomes higher.

The second charge-discharge cycle represents a charge-discharge cycle following a first charge-discharge cycle in which a discharge end voltage is acquired. A starting time of the second charge-discharge cycle is later than the ending time of the first charge-discharge cycle in which the discharge end voltage is acquired. The first charge-discharge cycle and the second charge-discharge cycle may be continuous, or a waiting period in which neither charging nor discharging exists may be included between the two charge-discharge cycles.

The first charge-discharge cycle may include a plurality of charge-discharge cycles. At least one of the highest voltage values in the respective plurality of charge-discharge cycles is set as the first voltage. Alternatively, a mean value, a median value, a minimum value, or a maximum value of the highest voltage values in the respective plurality of charge-discharge cycles may be set as the first voltage. The control unit 33 sets a second voltage representing a highest voltage value in a second charge-discharge cycle being a charge-discharge cycle following the plurality of charge-discharge cycles to a voltage lower than the first voltage. In such a case, another charge-discharge cycle may be included between the charge-discharge cycle acquiring the discharge end voltage and the second charge-discharge cycle.

The capacity measurement unit 34 measures a battery capacity by use of a current and a voltage acquired from the measurement unit 31. The capacity measurement unit 34 measures a full charge capacity of the battery module 20, by integrating current charged in a period from a time point when a discharge end voltage is measured to a time point when the battery module 20 reaches a fully charged state so as to calculate an integrated charge current. In charging during capacity measurement, a charge current value per unit time may vary. However, it is desirable to control the operation so as not to switch to discharging while charging. The method of measuring a battery capacity is not limited to the above, and a known capacity measurement method may be used. Additionally, the capacity measurement unit 34 may calculate a state of health (SOH) by use of a battery capacity calculated by the capacity measurement unit 34 and a full charge capacity in an unused, non-degraded state. An SOH in a non-degraded state of the battery module 20 is defined to be 100%. As the battery module 20 degrades, an SOH decreases.

The capacity measurement unit 34 transmits a calculated battery capacity and a calculated SOH to the control unit 33. The control unit 33 causes a storage unit to hold the received battery capacity. The control unit 33 may control charging and discharging of the battery module 20 on the basis of the received battery capacity. Further, the control unit 33 may display a remaining battery capacity based on the received battery capacity on a display unit in the electric power storage device 10, or transmit the remaining battery capacity to a user and an administrator of the electric power storage device 10 through the network.

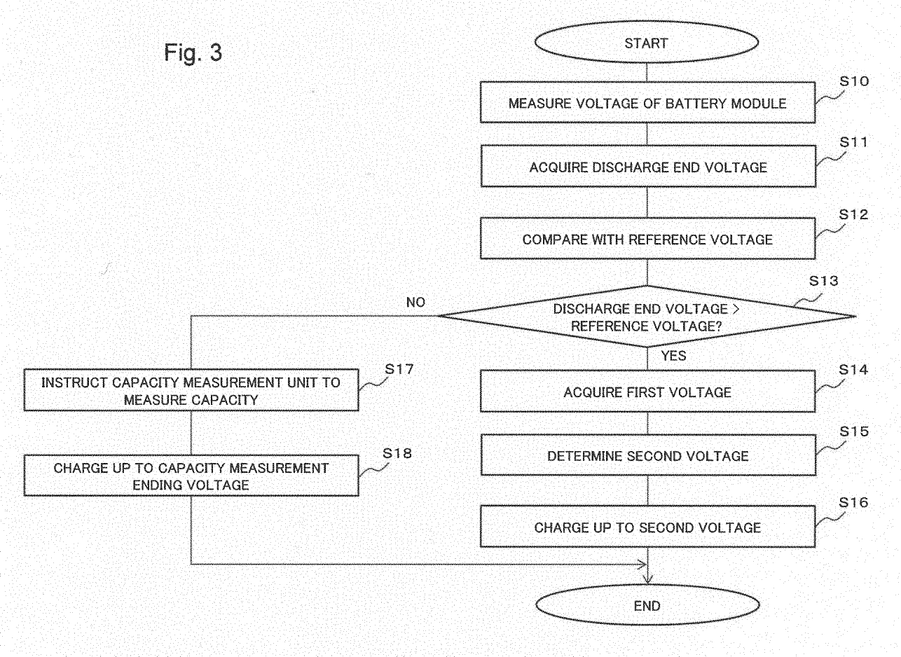

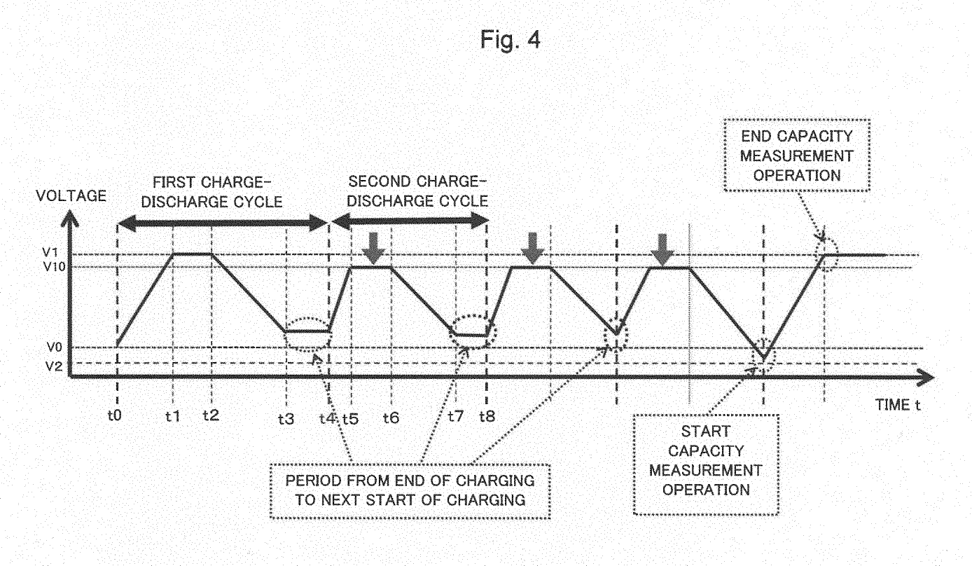

An operation of the control device 30 according to the present exemplary embodiment will be described by use of FIGS. 3 and 4.

FIG. 3 is a flowchart illustrating the operation of the control device 30 according to the present exemplary embodiment. FIG. 4 is a diagram illustrating an example of temporal change of a voltage in the electric power storage device 10. The electric power storage device 10 charges the battery module 20 with electric power in charging periods (from t0 to t1 and from t4 to t5). Then, charged electric power is discharged in discharging periods (from t2 to t3 and from t6 to t7). Waiting periods (from t1 to t2, from t3 to t4, from t5 to t6, and from t7 to t8) are periods other than charging and discharging. Further, in periods before t2, it is assumed that the battery module 20 repeats charging and discharging within a range from a lower discharge voltage limit V2 to a first voltage V1. Each of periods from t0 to t4 and from t4 to t8 is treated as one charge-discharge cycle.

In Step S10, the measurement unit 31 measures a voltage of the battery module 20. The measurement unit 31 transmits the measured voltage to the control unit 33.

In Step S11, the control unit 33 acquires from the measurement unit 31 a discharge end voltage representing a voltage in a period other than discharging and charging, and at the same time a voltage in a period from an end of discharging to a start of charging, in a charge-discharge cycle.

In Step S12, the control unit 33 compares the discharge end voltage with a reference voltage V0 representing a voltage at which capacity measurement is started. When the discharge end voltage is lower than or equal to the reference voltage, the control unit 33 proceeds to Step S17. On the other hand, when the discharge end voltage is higher than the reference voltage, the control unit 33 proceeds to Step S14.

In Step S14, the control unit 33 acquires a first voltage representing the highest voltage value in a charge-discharge cycle (first charge-discharge cycle) in which the discharge end voltage is acquired. The first voltage represents the highest voltage value in a charge-discharge cycle. The method of acquiring the first voltage is not particularly limited. For example, the storage unit may hold the highest voltage value in past charge-discharge cycles. The control unit 33 may acquire the highest voltage value in the charge-discharge cycle in which the discharge end voltage is acquired as the first voltage.

In Step S15, the control unit 33 determines a highest voltage value in a second charge-discharge cycle being a charge-discharge cycle following the first charge-discharge cycle. The charge-discharge cycle following the first charge-discharge cycle represents a charge-discharge cycle appearing later in the future than the first charge-discharge cycle. That is to say, a starting time t4 of the second charge-discharge cycle indicates a time later in the future than a starting time t0 of the first charge-discharge cycle. The control unit 33 sets a second voltage representing a highest voltage value in the second charge-discharge cycle to a voltage lower than the first voltage.

In the example illustrated in FIG. 4, it is assumed that a voltage in a period from t3 to t4 is acquired as a discharge end voltage in a charge-discharge cycle (first charge-discharge cycle) from t0 to t4. The voltage in the period from t3 to t4 is higher than the reference voltage V0. In this case, the control unit 33 sets a highest voltage value in the charge-discharge cycle from t4 to t8 (second charge-discharge cycle) to V10 being lower than the highest voltage value V1 in the charge-discharge cycle from t0 to t4. The charge-discharge unit 32 charges the battery module 20 up to V10 in the charging period from t4 to t5 in the second charge-discharge cycle from t4 to t8.

The control unit 33 may transmit the set second voltage to the storage unit. Additionally, the control unit 33 may transmit the second voltage to an external server, a user and an administrator of the electric power storage device 10, and the like through the network. Alternatively, the control unit 33 may transmit the second voltage to the display unit in the electric power storage device 10, and the display unit may output the second voltage.

In Step S16, the control unit 33 instructs the charge-discharge unit 32 to charge the battery module 20 up to the second voltage in the second charge-discharge cycle. The charge-discharge unit 32 connects the battery module 20 and the electric power supply source, and starts charging. Further, the charge-discharge unit 32 converts AC current supplied from the electric power supply source into DC current and supplies the current to the battery module 20. When the measurement unit 31 detects the second voltage, the control unit 33 instructs the charge-discharge unit 32 to end the charging of the battery module 20. The charge-discharge unit 32 interrupts the connection between the battery module 20 and the electric power supply source, and suspends charging of the battery module 20. In the example illustrated in FIG. 4, the electric power storage device 10 performs charging and discharging within a voltage range between the second voltage V10 and the reference voltage V0 in the second charge-discharge cycle and beyond. By setting the second voltage lower than the first voltage, charge energy of the electric power storage device 10 can be reduced.

In Step S17, the control unit 33 instructs the capacity measurement unit 34 to start capacity measurement. The capacity measurement unit 34 may start capacity measurement upon acquisition of a capacity measurement permission signal. The capacity measurement unit 34 acquires the reference voltage of the battery module 20 and a current at the reference voltage from the measurement unit 31.

In Step S18, the control unit 33 instructs the charge-discharge unit 32 to charge the battery module 20 up to the capacity measurement ending voltage. The charge-discharge unit 32 connects the battery module 20 and the electric power supply source, and starts charging. Further, the charge-discharge unit 32 converts AC current supplied from the electric power supply source into DC current and supplies the current to the battery module 20. The measurement unit 31 transmits a voltage and a current of the battery module 20 during charging to the control unit 33 and the capacity measurement unit 34. The capacity measurement unit 34 measures a battery capacity of the battery module 20 by use of the acquired current and the acquired voltage of the battery module 20. When the measurement of the battery capacity ends, the operation of the control device 30 ends.

While a voltage of the battery module 20 is used as a criterion of determining whether or not capacity measurement can be started in the description above, the criterion is not limited thereto. A stage of charge (SOC) of the battery module 20 may be used instead of a reference voltage. For example, it may be determined to lower an SOC at an upper charge limit when an SOC at a time point when discharging ends is greater than a reference capacity representing an SOC at a start of capacity measurement. Alternatively, the highest SOC value in the second charge-discharge cycle may be lowered instead of lowering the highest voltage value in the second charge-discharge cycle.

Further, the description above describes that capacity measurement is started when a discharge end voltage is lower than or equal to a reference voltage. However, capacity measurement may be started when a voltage during charging reaches the reference voltage. When the voltage during discharging reaches the reference voltage or less, the control unit 33 may instruct suspension of discharging of the battery module 20 and a start of capacity measurement. Alternatively, the control unit 33 may instruct a start of capacity measurement at a time point when the discharging ends.

As described above, when a discharge end voltage in a first charge-discharge cycle is higher than a reference voltage, the present exemplary embodiment sets a highest voltage value in a second charge-discharge cycle (second voltage) being a charge-discharge cycle following the first charge-discharge cycle to a value lower than a highest voltage value in the first charge-discharge cycle (first voltage). The present exemplary embodiment as described above is able to reduce charge energy of the electric power storage device 10. Accordingly, compared with a case that the battery module 20 is charged up to the first voltage, the possibility of charge energy charged in the electric power storage device 10 being less than or equal to an electric power supply amount (discharge energy) to the load becomes higher. That is to say, the possibility of the discharge end voltage being lower than or equal to the reference voltage becomes higher. Accordingly, capacity measurement can be performed without hampering convenience of a user of the electric power storage device 10.

Further, the present exemplary embodiment as described above is able to eliminate inconvenience that forced discharge is performed in order to start capacity measurement, preventing a user of the electric power storage device 10 from using electric power stored in the electric power storage device 10. For example, the present exemplary embodiment is able to eliminate inconvenience that electric power stored in a time period in which a power purchase price is low is forcibly discharged and then charged again.

### Second Exemplary Embodiment

Determination of whether or not capacity measurement can be started may start by an instruction from an administrator or a user of an electric power storage device 10, or an alarm held by the electric power storage device 10. Accordingly, the present exemplary embodiment sets a second voltage lower than a first voltage when a capacity measurement permission signal is received.

Similarly to the first exemplary embodiment, an example of a functional block diagram of an electric power storage device 10 according to the present exemplary embodiment can be illustrated by FIG. 1. The electric power storage device 10 according to the present exemplary embodiment includes a battery module 20 and a control device 30. The control device 30 includes a measurement unit 31, a charge-discharge unit 32, a control unit 33, and a capacity measurement unit 34. With regard to a function similar to the first exemplary embodiment, description thereof is appropriately omitted in the following description.

The measurement unit 31 is connected to both terminals of a lithium ion secondary battery and measures a voltage of the battery module 20. Further, the measurement unit 31 measures a discharge current from the battery module 20 and a charge current to the battery module 20. The measurement unit 31 transmits the measured voltage and the measured current to the control unit 33. Further, the measurement unit 31 may transmit the measured voltage and the measured current to the capacity measurement unit 34.

The charge-discharge unit 32 charges and discharges the battery module 20 in accordance with an instruction from the control unit 33. Further, the charge-discharge unit 32 is able to convert DC current discharged by the battery module 20 into AC current and convert AC current supplied from a distribution system into DC current.

The control unit 33 instructs the charge-discharge unit 32 to charge the battery module 20 and discharge the battery module 20. When receiving a capacity measurement permission signal, the control unit 33 acquires, as a first voltage, the highest voltage value in charge-discharge cycles at times before the time of receiving the capacity measurement permission signal. The control unit 33 sets a second voltage representing a highest voltage value in a second charge-discharge cycle being a charge-discharge cycle following a charge-discharge cycle in which the first voltage is acquired to a voltage lower than the first voltage.

After receiving the capacity measurement permission signal, the control unit 33 acquires a discharge end voltage, and compares the acquired discharge end voltage with a reference voltage. When the discharge end voltage is lower than or equal to the reference voltage, the control unit 33 determines that capacity measurement can be started. The control unit 33 transmits a capacity measurement permission signal to the capacity measurement unit 34 to start capacity measurement. Further, the control unit 33 instructs the charge-discharge unit to charge the battery module 20 up to a capacity measurement ending voltage. Alternatively, the control unit 33 may activate a capacity measurement mode.

When the discharge end voltage is higher than the reference voltage, the control unit 33 determines that capacity measurement cannot be started. The control unit 33 instructs the charge-discharge unit 32 to charge the battery module 20 up to the second voltage.

The capacity measurement permission signal is a signal permitting or instructing a start of capacity measurement. Alternatively, the capacity measurement permission signal may be a signal permitting or instructing the electric power storage device 10 to operate in a capacity measurement mode. The capacity measurement mode may be a mode in which the control unit 33 starts determination of whether or not capacity measurement can be started. Alternatively, the capacity measurement mode may be a mode in which the capacity measurement unit 34 performs capacity measurement. Alternatively, the capacity measurement mode may be a mode including determination of whether or not capacity measurement can be started and capacity measurement.

The method of the control unit 33 acquiring a capacity measurement permission signal is not particularly limited. For example, a storage unit in the control device 30 may hold a capacity measurement schedule previously indicating a date and time to start capacity measurement. The control unit 33 may acquire the capacity measurement schedule from the storage unit as a capacity measurement permission signal. Alternatively, a user or an administrator of the electric power storage device 10 may transmit a capacity measurement permission signal to the electric power storage device 10. The control unit 33 is able to receive the capacity measurement permission signal through a network.

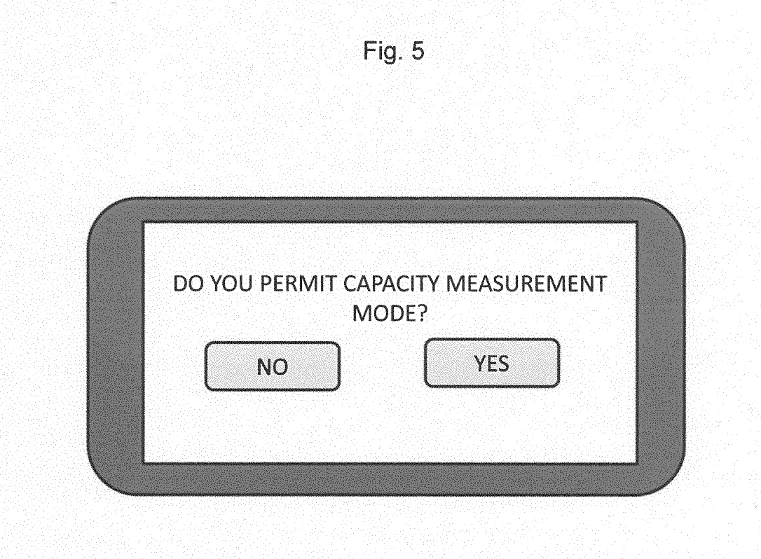

Alternatively, the control unit 33 may display an indication on a display unit in the electric power storage device asking permission to transmit a capacity measurement permission signal as illustrated in FIG. 5. For example, when receiving a capacity measurement permission signal from the storage unit, an external server, or the like, the control unit 33 may display a message such as “DO YOU PERMIT CAPACITY MEASUREMENT MODE?” on the display unit. When receiving a signal indicating “YES (permit)” from a user of the electric power storage device 10, an operation in the capacity measurement mode can be started.

The method of the control unit 33 lowering a highest voltage value is not particularly limited. The control unit 33 may divide a first voltage by a certain value, or multiply a first voltage by any value less than or equal to one. Alternatively, the control unit 33 may determine, as a second voltage, a voltage by which future discharge energy estimated in accordance with a usage history of the electric power storage device 10, electric power demand of a load, and the like can be maintained. For example, a home energy management system (HEMS) or a watt meter calculates energy demand of a load and a user that receive electric power supply from the electric power storage device 10, and a predicted value thereof. The HEMS or the watt meter transmits the calculated energy demand and the calculated predicted value thereof to the control unit 33 through the network. The control unit 33 may determine a second voltage so that a charge capacity is lower than or equal to the acquired energy demand.

By setting a second voltage lower than a first voltage, a remaining chargeable capacity of the electric power storage device 10 can be reduced. Accordingly, compared with a case that the electric power storage device 10 is charged up to the first voltage, the possibility of charge energy charged in the electric power storage device 10 being lower than discharge energy to the load becomes higher. That is to say, the possibility of charge energy being less than discharge energy, and a discharge end voltage in a charge-discharge cycle being lower than or equal to a reference voltage becomes higher. Consequently, a full charge capacity becomes more detectable.

The capacity measurement unit 34 measures a battery capacity by use of a current and a voltage acquired from the measurement unit 31. The capacity measurement unit 34 transmits the calculated battery capacity and a calculated SOH to the control unit 33. The control unit 33 holds the acquired battery capacity in the storage unit. The control unit 33 is able to control charging and discharging of the battery module 20 on the basis of the acquired battery capacity. Further, the control unit 33 may display a remaining battery capacity based on the acquired battery capacity on the display unit in the electric power storage device 10, or transmit the battery capacity to a user and an administrator of the electric power storage device 10 through the network.

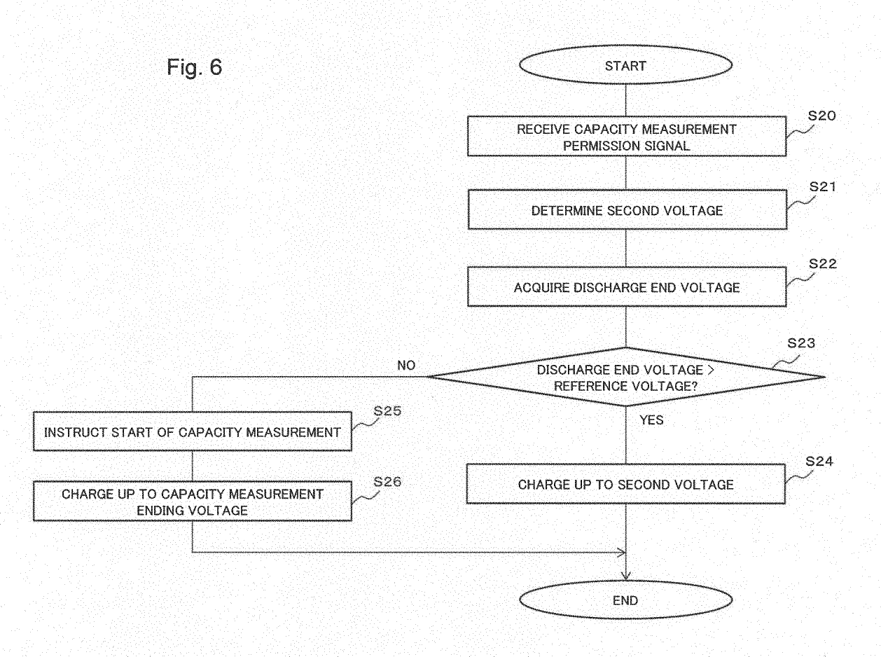

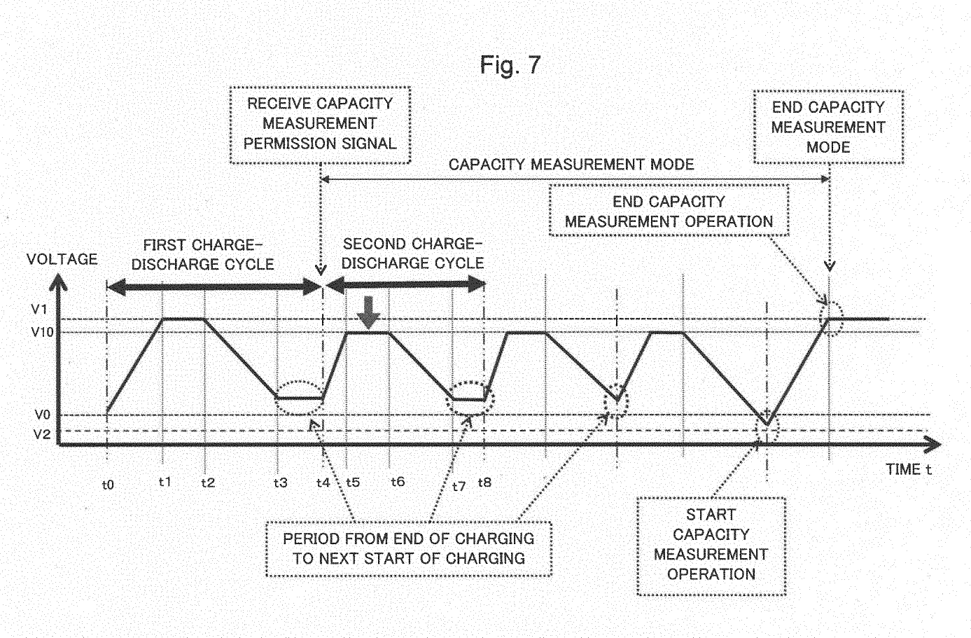

An example of an operation of the control device 30 according to the present exemplary embodiment will be described by use of FIGS. 6 and 7. FIG. 6 is a flowchart illustrating the operation of the control device 30 according to the present exemplary embodiment. FIG. 7 is a diagram illustrating an example of temporal change of a voltage in the electric power storage device 10. The electric power storage device 10 charges the battery module 20 with electric power in charging periods (from t0 to t1 and from t4 to t5). Further, the electric power storage device 10 is able to discharge electric power in discharging periods (from t2 to t3 and from t6 to t7). Periods from t1 to t2, from t3 to t4, from t5 to t6, and from t7 to t8 are periods other than charging and discharging (waiting periods). Further, in periods before to, it is assumed that the battery module 20 repeats charging and discharging within a range from a lower discharge voltage limit V2 to a voltage V1. A period from the time t0 to the time t4 is referred to as a first charge-discharge cycle, and a period from the time t4 to the time t8 is referred to as a second charge-discharge cycle.

In Step S20, the control unit 33 acquires a capacity measurement permission signal being a signal instructing capacity measurement. Upon acquisition of the capacity measurement permission signal, the control unit 33 may instruct an operation of the electric power storage device 10 in the capacity measurement mode. In the example illustrated in FIG. 6, it is assumed that a capacity measurement permission signal is received at the time point t2.

In Step S21, the control unit 33 acquires, as a first voltage, the highest voltage value in charge-discharge cycles up to the time at which the capacity measurement permission signal is received. The control unit 33 sets a second voltage representing a highest voltage value in a charge-discharge cycle at a time later than the time at which the capacity measurement permission signal is received to a voltage lower than the first voltage. In the example illustrated in FIG. 6, it is assumed that the capacity measurement permission signal is received at the time t4. The control unit 33 acquires the first voltage V1 representing the highest voltage value in the first charge-discharge cycle (from t0 to t4) as the first voltage. The control unit 33 sets the second voltage being a highest voltage value in a charge-discharge cycle after the time t4 to V10 being lower than the first voltage V1. The control unit 33 holds the set second voltage in the storage unit. Additionally, the control unit 33 may transmit the second voltage to an external server, a user and an administrator of the electric power storage device 10, and the like through the network. Alternatively, the control unit 33 may display the second voltage on the display unit in the electric power storage device 10.

In Step S22, the control unit 33 acquires from the measurement unit 31 a discharge end voltage representing a voltage in a period other than discharging and charging, and at the same time a voltage in a period from an end of discharging to a next start of charging.

In Step S23, the control unit 33 compares the discharge end voltage with a reference voltage V0 representing a voltage at which capacity measurement is started.

When the discharge end voltage is higher than the reference voltage, the control unit 33 instructs the charge-discharge unit 32 to charge the battery module 20 up to the second voltage V10 in Step S24. The charge-discharge unit 32 receiving the instruction interrupts connection between the battery module 20 and an electric power supply source, and ends charging of the battery module 20. The above concludes the operation of the control device 30. In a period of operation in the capacity measurement mode, the electric power storage device 10 is able to perform charging and discharging within a range from the voltage V10 to the reference voltage V0. By setting the second voltage lower than the first voltage, charge energy of the electric power storage device 10 can be reduced.

On the other hand, when the discharge end voltage is lower than or equal to the reference voltage, the control unit 33 instructs the capacity measurement unit 34 to start capacity measurement (Step S25).

In Step S26, the control unit 33 instructs the charge-discharge unit 32 to charge the battery module 20 up to a capacity measurement ending voltage. The charge-discharge unit 32 connects the battery module 20 and the electric power supply source, and starts charging. Further, electric power is supplied from the connected electric power supply source to the battery module 20. The measurement unit 31 transmits a voltage and a current of the battery module 20 during charging to the control unit 33 and the capacity measurement unit 34. The capacity measurement unit 34 measures a battery capacity of the battery module by use of the acquired current and the acquired voltage of the battery module. When the measurement of the battery capacity ends, the operation of the control device 30 ends.

As described above, the present exemplary embodiment is able to provide effects similar to those according to the first exemplary embodiment.

Further, when acquiring a capacity measurement permission signal, the present exemplary embodiment sets a second voltage representing a highest voltage value in a charge-discharge cycle at a time later than the time at which the capacity measurement permission signal is received to a voltage lower than a first voltage representing the highest voltage value in a charge-discharge cycle at a time earlier than the time at which the capacity measurement permission signal is received. The present exemplary embodiment as described above is able to lower a highest voltage value in a charge-discharge cycle at a timing when capacity measurement is permitted, regardless of operating status (discharging, charging, or inactive) of the electric power storage device 10. Further, the second voltage can be determined without determination of whether or not capacity measurement can be started, and therefore a processing amount of the control unit 33 can be reduced.

### Third Exemplary Embodiment

Whether or not a discharge end voltage reaches a reference voltage depends on electric power demand of a user of an electric power storage device 10. Accordingly, when charge energy from a highest voltage value in a charge-discharge cycle to the reference voltage is greater than discharge energy from a battery module 20, capacity measurement cannot be started. Accordingly, the present exemplary embodiment is set to lower a highest value in a charge-discharge cycle as charge-discharge cycles are repeated.

Similarly to the first exemplary embodiment, an example of a functional block diagram of an electric power storage device 10 according to the present exemplary embodiment is illustrated in FIG. 1. The electric power storage device 10 according to the present exemplary embodiment includes a battery module 20 storing or releasing electric power, and a control device 30. The control device 30 includes a measurement unit 31 measuring a voltage of the battery module 20, a charge-discharge unit 32 enabling connection between the battery module 20 and a distribution system, a capacity measurement unit 34 measuring a battery capacity of the battery module 20, and a control unit 33 controlling an entire operation of the control device 30 including the measurement unit 31, the charge-discharge unit 32, and the capacity measurement unit 34. With regard to a function similar to the first exemplary embodiment, description thereof is appropriately omitted in the following description.

The measurement unit 31 is connected to both terminals of a lithium ion secondary battery and measures a voltage of the battery module 20. Further, the measurement unit 31 measures a discharge current from the battery module 20 and a charge current to the battery module 20. The measurement unit 31 transmits the measured voltage and the measured current to the control unit 33. Further, the measurement unit 31 transmits the measured voltage and the measured current to the capacity measurement unit 34.

The charge-discharge unit 32 charges and discharges the battery module 20 in accordance with an instruction from the control unit 33. The charge-discharge unit 32 is able to convert DC current discharged from the battery module 20 into AC current, and convert AC current supplied from the distribution system into DC current.

The control unit 33 determines whether or not capacity measurement for calculating a battery capacity can be started by use of a discharge end voltage acquired from the measurement unit 31. The control unit 33 acquires from the measurement unit 31 the discharge end voltage representing a voltage in a period other than discharging and charging, and at the same time a voltage in a period from an end of discharging to a start of charging. The control unit 33 compares the discharge end voltage with a reference voltage. When the discharge end voltage is lower than or equal to the reference voltage, the control unit 33 determines that capacity measurement can be performed. When capacity measurement can be started, the control unit 33 instructs the charge-discharge unit 32 to charge the battery module 20 up to a capacity measurement ending voltage. Further, the control unit 33 instructs the capacity measurement unit 34 to start capacity measurement of the battery module 20.

On the other hand, when the discharge end voltage is higher than the reference voltage, the control unit 33 determines that capacity measurement cannot be started. The control unit 33 acquires, as a first voltage, the highest voltage value in the charge-discharge cycle in which the discharge end voltage is acquired. A plurality of charge-discharge cycles may be acquired as a first charge-discharge cycle. The first voltage may be any one of the highest voltage values in the respective plurality of charge-discharge cycles. Alternatively, the first voltage may be a mean value, a median value, a minimum value, or a maximum value of the highest voltage values in the respective plurality of charge-discharge cycles.

The control unit 33 sets a second voltage representing a highest voltage value in a second charge-discharge cycle being a charge-discharge cycle following the first charge-discharge cycle to a voltage lower than the first voltage. Additionally, the control unit 33 instructs the charge-discharge unit 32 to charge the battery module 20 up to the second voltage. The operation described above is repeated until a discharge end voltage becomes lower than or equal to the reference voltage.

The method of the control unit 33 setting a second voltage lower than a first voltage is not particularly limited. For example, a value obtained by multiplying or dividing a highest value in a charge-discharge cycle held by the control unit 33 by a certain value less than one may be used. Alternatively, a number of times a start of capacity measurement is determined not permitted, or a number of charge-discharge cycles in which a start of capacity measurement is determined not permitted is acquired. In accordance with the number, the control unit 33 may assign a weight to the value by which the highest voltage value in the charge-discharge cycle is divided or multiplied. Alternatively, the control unit 33 may previously hold a table associating a number of times a start of capacity measurement is determined not permitted with a highest voltage value in a charge-discharge cycle. The control unit 33 may refer to the correspondence table to set a corresponding highest voltage value. Alternatively, the control unit 33 may determine a value by which the highest voltage value in the first charge-discharge cycle is divided or multiplied, in accordance with a time (e.g. one day or one week) elapsed from a start of determination of whether or not capacity measurement can be started.

The capacity measurement unit 34 measures a battery capacity by use of a current and a voltage acquired from the measurement unit 31. The capacity measurement unit 34 measures a full charge capacity of the battery module 20, by integrating current charged in a period from a time point when the discharge end voltage is measured to a time point when the battery module 20 reaches a fully charged state so as to calculate an integrated charge current. The method of measuring a battery capacity is not limited to the above, and a known capacity measurement method may be used.

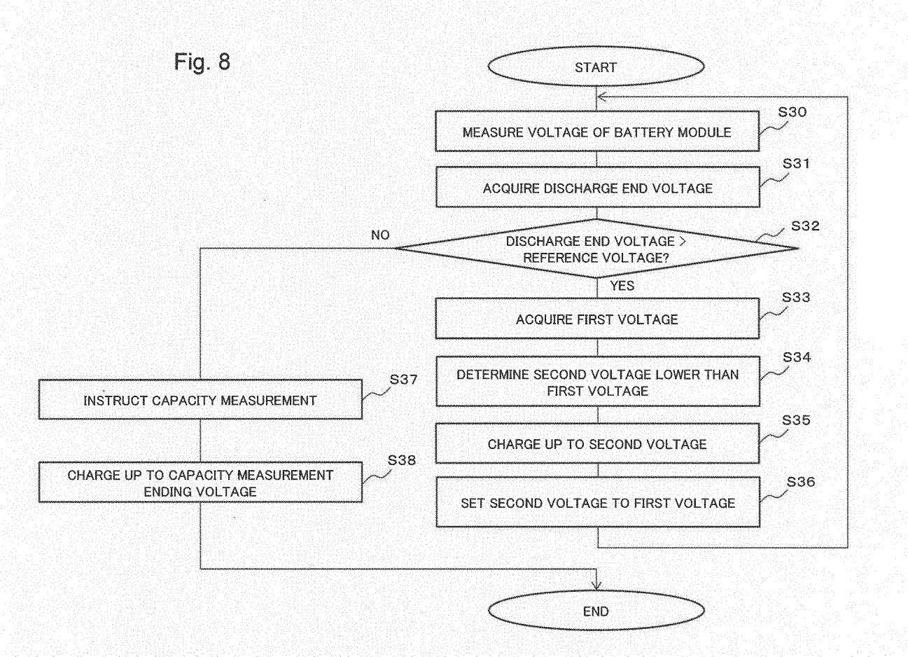

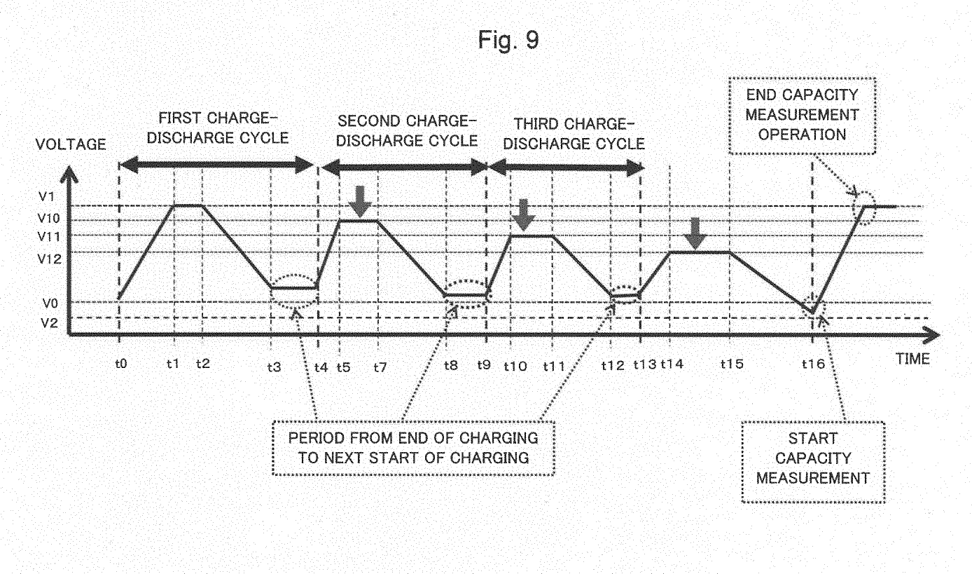

An example of an operation of the control device 30 according to the present exemplary embodiment will be described by use of FIGS. 8 and 9. FIG. 8 is a flowchart illustrating an example of the operation of the control device 30 according to the present exemplary embodiment. FIG. 9 is a diagram illustrating an example of temporal change of a voltage in the electric power storage device 10 according to the present exemplary embodiment. The electric power storage device 10 charges the battery module 20 with electric power in charging periods (from t0 to t1, from t4 to t5, from t9 to t10, and from t13 to t14). Further, electric power stored in the battery module 20 is discharged in discharging periods (from t2 to t3, from t7 to t8, from t11 to t12, and from t15 to t16). In the example in FIG. 9, each of periods from t0 to t4, from t4 to t9, from t9 to t13, and from t13 to t16 is treated as one charge-discharge cycle. Further, in periods before to, it is assumed that the battery module 20 repeats charging and discharging within a range from a lower discharge voltage limit V2 to a first voltage V1.

In Step S30, the measurement unit 31 measures a voltage of the battery module 20 in a period from an end of discharging to a start of charging. The measurement unit 31 transmits the measured voltage to the control unit 33.

In Step S31, the control unit 33 acquires from the measurement unit 31 a discharge end voltage representing a voltage in a period other than discharging and charging, and at the same time a voltage in a period from an end of discharging to a next start of charging.

In Step S32, the control unit 33 compares the acquired discharge end voltage with a reference voltage representing a voltage at which capacity measurement is started. When the discharge end voltage exhibits a value greater than the reference voltage (t=t3 to t4, t=t8 to t9, and t=t12 to t13), the control unit 33 proceeds to Step S33. When the discharge end voltage is lower than or equal to the reference voltage, the control unit 33 proceeds to Step S37.

In Step S33, the control unit 33 acquires, as the first voltage, the highest voltage value in the charge-discharge cycle in which the discharge end voltage is acquired. Additionally, the control unit 33 may acquire an initial value of the highest voltage value defined by a manufacturer, a management company, a user, or the like of the electric power storage device 10. In the example illustrated in FIG. 9, it is assumed that the control unit 33 acquires V1 being the highest voltage value in a first charge-discharge cycle (from t0 to t4) being a charge-discharge cycle including the discharge end voltage at t2.

In Step S34, the control unit 33 determines a second voltage representing a highest voltage value in a second charge-discharge cycle being a charge-discharge cycle following the first charge-discharge cycle. Since the highest voltage value in the first charge-discharge cycle from t0 to t4 in FIG. 9 is V1, a highest voltage value in the second charge-discharge cycle from t4 to t9 is set to V10 being lower than V1.

The method of setting a second voltage lower than a first voltage is not particularly limited. For example, a second voltage may be calculated by multiplying the first voltage by a certain value less than one, or by dividing the first voltage by a certain value. Alternatively, the control unit 33 acquires a number of times a start of capacity measurement is determined not permitted or a number of charge-discharge cycles in which a start of capacity measurement is determined not permitted. In accordance with the number, the control unit 33 may assign a weight to the value by which the first voltage is divided or multiplied. Alternatively, the control unit 33 may previously hold a table associating a number of times a start of capacity measurement is determined not permitted with a highest voltage value in a charge-discharge cycle. The control unit 33 may refer to the correspondence table to set a second voltage.

Alternatively, the control unit 33 may determine a value by which the first voltage is divided or multiplied, in accordance with a time (e.g. one day or one week) elapsed from a start of determination of whether or not capacity measurement can be started. An initial value of a highest voltage value in a charge-discharge cycle may be divided or multiplied by a certain value. In this case, a calculated second voltage is calculated so as to be lower than the highest voltage value in the immediately preceding charge-discharge cycle.

The control unit 33 holds the second voltage in a storage unit. Additionally, the control unit 33 may transmit the second voltage to an external server, a user and an administrator of the electric power storage device 10, and the like through a network. Alternatively, the control unit 33 may display the second voltage on a display unit in the electric power storage device 10.

In Step S35, the control unit 33 instructs the charge-discharge unit 32 to charge the battery module 20 up to the second voltage. The charge-discharge unit 32 establishes connection so that electric power can be supplied from an electric power supply source to the battery module 20. Further, the charge-discharge unit 32 converts AC current supplied from the electric power supply source into DC current, and supplies the current to the battery module 20.

In Step S36, the control unit 33 sets the second upper voltage limit to a first voltage. Upon setting the second voltage to the first voltage, the control unit 33 returns to Step S30. Steps S30 to S36 are thereafter repeated until a discharge end voltage becomes lower than or equal to the reference voltage. The control unit 33 may hold the second voltage intact. In such a case, a third voltage lower than the second voltage may be determined in next Steps from S30 to S35.

On the other hand, when the discharge end voltage turns out to be lower than or equal to the reference voltage in Step S32 (t=t16), the control unit 33 proceeds to Step S37. In Step S37, the control unit 33 instructs the capacity measurement unit 34 to start capacity measurement. Upon acquisition of a capacity measurement permission signal, the capacity measurement unit 34 starts capacity measurement. The capacity measurement unit 34 acquires the reference voltage of the battery module 20 and a current at the reference voltage from the measurement unit 31.

In Step S38, the control unit 33 instructs the charge-discharge unit 32 to charge the battery module 20 up to the capacity measurement ending voltage. In this case, the setting of the second voltage may be cleared. Alternatively, the capacity measurement ending voltage may be set as a highest voltage value. The charge-discharge unit 32 establishes connection so that electric power can be supplied from the electric power supply source to the battery module 20. Further, the charge-discharge unit 32 converts AC current supplied from the electric power supply source into DC current and supplies the current to the battery module 20. The measurement unit 31 transmits a voltage and a current of the battery module 20 during charging to the control unit 33 and the capacity measurement unit 34. The capacity measurement unit 34 measures a battery capacity of the battery module by use of the acquired current and the acquired voltage of the battery module. The above concludes the operation of the control device 30.

FIG. 9 illustrates an example of charge-discharge cycles performing the operations from Steps S30 to S38. A period from a start of charging to an end of discharging is treated as one cycle. As illustrated in FIG. 9, a discharge end voltage in the first charge-discharge cycle from t0 to t4 is higher than the reference voltage. Accordingly, in the second charge-discharge cycle from t4 to t9, the charge-discharge unit 32 charges the battery module 20 up to the second voltage being lower than the highest voltage value V1 in the first charge-discharge cycle from t0 to t4. Similarly, the charge-discharge unit 32 sets a highest voltage value (third voltage) in a third charge-discharge cycle from t9 to t13 to a value lower than the highest voltage value (second voltage) in the second charge-discharge cycle from t4 to t9. Thus, as charge-discharge cycles are repeated, a highest voltage value in a charge-discharge cycle becomes lower such as from V1 to V10 to V11. A discharge end voltage in a charge-discharge cycle from t13 to t16 is lower than or equal to the reference voltage, and therefore, in and after the charge-discharge cycle from t13 to t16, the battery module 20 is charged up to a capacity measurement ending voltage.

The capacity measurement permission signal may be acquired similarly to the second exemplary embodiment. The control unit 33 may determine the second voltage when receiving the capacity measurement permission signal. Alternatively, the control unit 33 may preset a charge schedule so that a highest voltage value becomes lower as charge-discharge cycles repeat in a capacity measurement mode.

As described above, the present exemplary embodiment is able to provide effects similar to those according to the first and the second exemplary embodiments.

Further, the present exemplary embodiment lowers a second voltage as a number of times a start of capacity measurement is determined not permitted, or a period in which a start of capacity measurement is determined not permitted increases. The present exemplary embodiment as described above is able to mitigate inconvenience that the electric power storage device 10 repeats charging and discharging within a range between a reference voltage and a second voltage, and capacity measurement cannot be started. A discharge end voltage not reaching the reference voltage represents a case that charged electric power is not fully utilized, and electric power demand and charge energy of the electric power storage device 10 are not balanced. The present exemplary embodiment lowers a highest voltage value every time a charge-discharge cycle is repeated, and therefore charge energy of the electric power storage device 10 can be brought close to actual electric power demand.

### Fourth Exemplary Embodiment

According to the first to the third exemplary embodiments, when capacity measurement cannot be started, the control unit 33 charges the battery module 20 to a second voltage. However, there may be a case that a starting time of capacity measurement is preferably advanced, in accordance with a degradation level of the electric power storage device 10, or a request by a user or the like of the electric power storage device 10. In such a case, there is a possibility of inconvenience that capacity measurement cannot be started until the battery module 20 is charged up to the second voltage. Accordingly, an electric power storage device 10 according to the present exemplary embodiment suspends charging of a battery module 20 when a certain condition is satisfied.

Similarly to the first to the third exemplary embodiments, an example of a functional block diagram of the electric power storage device 10 according to the present exemplary embodiment is illustrated in FIG. 1. The electric power storage device 10 according to the present exemplary embodiment includes the battery module 20 and a control device 30. The control device 30 includes a measurement unit 31, a charge-discharge unit 32, a control unit 33, and a capacity measurement unit 34. Configurations of the measurement unit 31 and the capacity measurement unit 34 are similar to those according to the first to the third exemplary embodiments. Difference from the first to the third exemplary embodiments will be described below.

The measurement unit 31 is connected to both terminals of a lithium ion secondary battery and measures a voltage of the battery module 20. Further, the measurement unit 31 measures a discharge current from the battery module 20 and a charge current to the battery module 20. The measurement unit 31 transmits the measured voltage and the measured current to the control unit 33. The measurement unit 31 may transmit the measured voltage and the measured current to the capacity measurement unit 34.

The charge-discharge unit 32 charges and discharges the battery module 20 in accordance with an instruction from the control unit 33. Further, the charge-discharge unit 32 is able to convert DC current discharged by the battery module 20 into AC current and convert AC current supplied by a distribution system into DC current.

By use of a discharge end voltage, the control unit 33 determines whether or not capacity measurement measuring a battery capacity can be started. The control unit 33 acquires from the measurement unit 31 the discharge end voltage representing a voltage in a period other than discharging and charging, and at the same time a voltage in a period from an end of discharging to a next start of charging. The control unit 33 compares the discharge end voltage with a reference voltage. When the discharge end voltage is lower than or equal to the reference voltage, the control unit 33 determines that capacity measurement can be performed. When capacity measurement can be started, the control unit 33 instructs the charge-discharge unit 32 to charge the battery module 20 up to a capacity measurement ending voltage representing a voltage at which capacity measurement is ended. Further, the control unit 33 instructs the capacity measurement unit 34 to start capacity measurement of the battery module 20.

When the discharge end voltage is higher than the reference voltage, the control unit 33 determines that capacity measurement cannot be started. When the discharge end voltage is higher than the reference voltage, the control unit 33 acquires charge-discharge history information indicating a usage history of the electric power storage device 10, and a charge suspension condition indicating a condition for suspending charging of the battery module 20.

When a usage history of the electric power storage device indicated by the charge-discharge history information satisfies the charge suspension condition, the control unit 33 instructs suspension of charging of the battery module 20. In other words, the electric power storage device 10 operates in a charging or waiting state until the discharge end voltage becomes lower than the reference voltage.

On the other hand, when a usage history of the electric power storage device 10 indicated by the charge-discharge history information does not satisfy the charge suspension condition, the control unit 33 acquires a first voltage representing a highest voltage value in a first charge-discharge cycle being a charge-discharge cycle in which the discharge end voltage is acquired. The control unit 33 sets a second voltage representing a highest voltage value in a charge-discharge cycle following the first charge-discharge cycle to a voltage lower than the first voltage.

The charge suspension condition indicates a condition for suspending charging of the battery module 20. The charge-discharge suspension condition indicates a state of the electric power storage device 10 in which a start of capacity measurement is preferably given priority. For example, the charge suspension condition may use a period of use and a degradation level of the electric power storage device 10. Rapid capacity measurement can be performed on an electric power storage device 10 in which a difference between a measured full charge capacity and an actual full charge capacity tends to be large.

Alternatively, the charge suspension condition may be a number of times a start of capacity measurement is successively determined not permitted, or a number of times a second voltage is determined. Alternatively, the charge suspension condition may be a number of charge-discharge cycles, discharging periods, or charging periods after receiving a capacity measurement permission signal, or a time (e.g. one day or one week) elapsed after acquiring a capacity measurement permission signal. By suspending discharging when the values are greater than or equal to certain values, a period in which a start of capacity measurement is determined not permitted can be shortened. Further, inconvenience that capacity measurement cannot be started because of low electric power demand of a load can be eliminated.

As another example, a first voltage value or an SOC may be used as the charge suspension condition. Alternatively, a time to a start time limit or an ending time limit of capacity measurement set by a user or an administrator of the electric power storage device 10 may be used.

The charge-discharge history information is information indicating usage histories of the electric power storage device and the battery module 20. For example, the charge-discharge history information may include a period of use of the electric power storage device 10 and frequency of charging and discharging. Alternatively, the charge-discharge history information may include a number of times a start of capacity measurement is successively determined not permitted or a number of times a highest voltage value in a charge-discharge cycle is lowered. Alternatively, the charge-discharge history information may include the first voltage, and charge energy (Wh) and an SOC in the first charge-discharge cycle. Alternatively, the charge-discharge history information may include a time elapsed from receiving a capacity measurement permission signal and a time elapsed from a start of determination of whether or not capacity measurement can be started. The charge-discharge history information to be acquired may be changed in accordance with the charge suspension condition.

The method of acquiring charge-discharge history information and a charge suspension condition is not particularly limited. For example, a storage unit in the control device 30 may previously hold charge-discharge history information and a charge suspension condition, and the control unit 33 may acquire the charge-discharge history information and the charge suspension condition from the storage unit. Alternatively, charge-discharge history information and a charge suspension condition may be acquired from an external server. Alternatively, an indication requesting entry of charge-discharge history information and a discharge suspension condition may be displayed on a display unit in the electric power storage device 10 or a display unit of a computer of a user or an administrator of the electric power storage device 10. The control unit 33 may acquire entered charge-discharge history information and an entered discharge suspension condition.

The capacity measurement unit 34 measures a battery capacity by use of a current and a voltage acquired from the measurement unit 31. The capacity measurement unit 34 measures a full charge capacity of the battery module 20, by integrating current charged in a period from a time point when a discharge end voltage is measured to a time point when the battery module 20 reaches a fully charged state so as to calculate an integrated charge current.

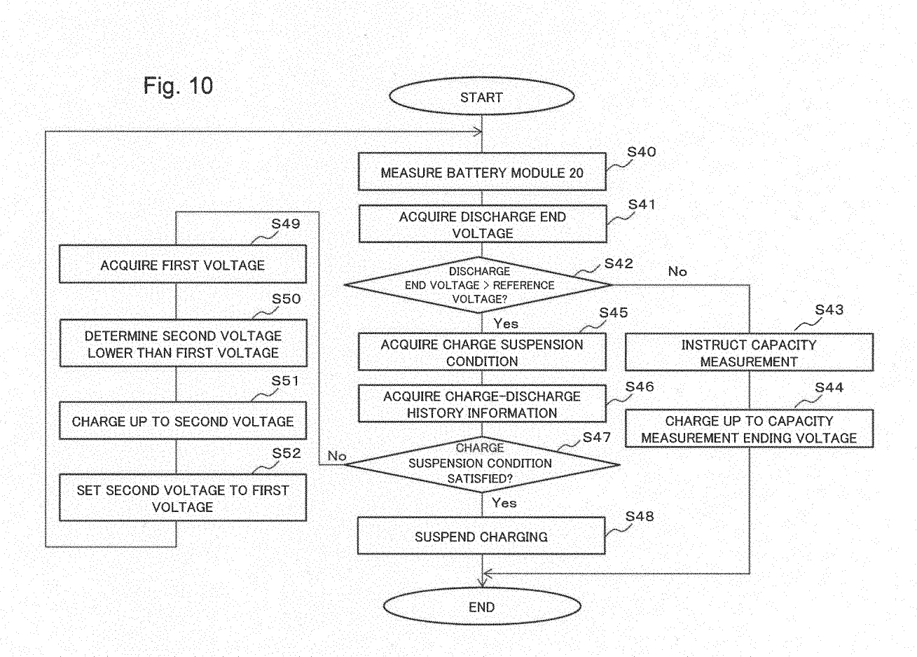

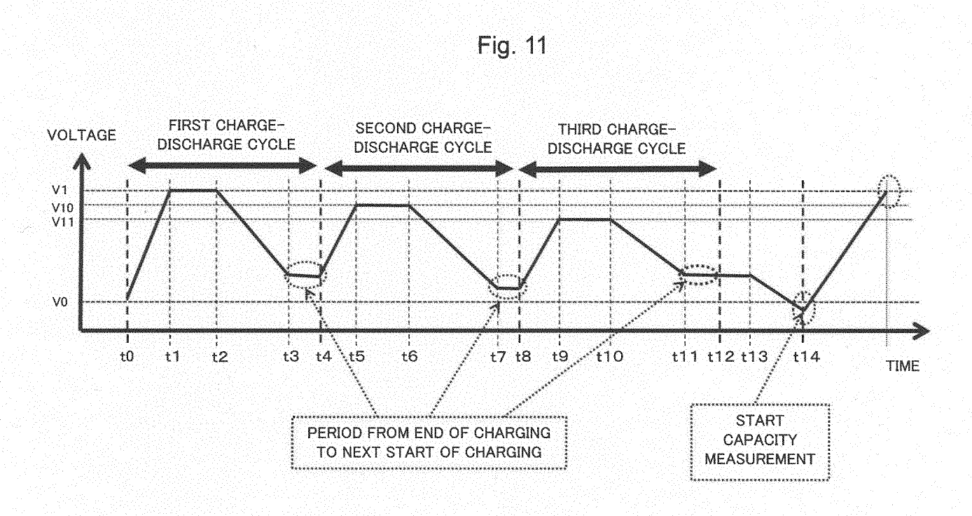

An operation of the control device 30 according to the present exemplary embodiment will be described by use of FIGS. 10 and 11. FIG. 10 is a flowchart illustrating an example of the operation of the control device 30 according to the present exemplary embodiment. FIG. 11 illustrates an example of charge-discharge cycles in the electric power storage device 10 according to the present exemplary embodiment. The electric power storage device 10 charges the battery module 20 with electric power in charging periods (from t0 to t1, from t4 to t5, and from t8 to t9). Then, the electric power storage device 10 discharges electric power from the battery module 20 in discharging periods (from t2 to t3, from t6 to t7, from t10 to t11, and from t13 to t14). Waiting periods (from t1 to t2, from t3 to t4, from t5 to t6, from t7 to t8, from t9 to t10, from t11 to t12, and from t12 to t13) are periods other than charging and discharging. Each of periods from t0 to t4, from t4 to t8, and from t8 to t12 is treated as one charge-discharge cycle. In periods before t0, the battery module 20 repeats charging and discharging within a range from a lower discharge voltage limit V2 to a highest voltage value V1.

In Step S40, the measurement unit 31 measures a voltage of the battery module 20. The measurement unit 31 transmits the measured voltage to the control unit 33. It is assumed that the control unit 33 measures a discharge end voltage at t2.

In Step S41, the control unit 33 acquires from the measurement unit 31 a discharge end voltage representing a voltage in a period other than discharging and charging, and at the same time a voltage in a period from an end of discharging to a start of charging.

In Step S42, the control unit 33 compares the acquired discharge end voltage with a reference voltage representing a voltage at which capacity measurement is started. When the discharge end voltage is lower than or equal to the reference voltage, the control unit 33 proceeds to Step S43. When the discharge end voltage is higher than the reference voltage, the control unit 33 proceeds to Step S45.

In Step S45, the control unit 33 acquires a charge suspension condition indicating a condition for suspending charging of the battery module 20. The charge-discharge suspension condition indicates a state of the electric power storage device 10 in which a start of capacity measurement is preferably given priority. In the example illustrated in FIG. 11, it is assumed that the control unit 33 acquires a charge suspension condition that “charging is suspended when a first voltage is lower than or equal to V11.”

In Step S46, the control unit 33 acquires charge-discharge history information indicating a past usage history of the electric power storage device 10. For example, as the charge-discharge history information, the highest voltage value in past charging periods and an upper SOC limit may be acquired. Alternatively, a number of discharging periods in which a start of capacity measurement is determined not permitted may be acquired. As another example, periods of use and degradation levels of the electric power storage device 10 and the battery module 20 may be acquired. In the example illustrated in FIG. 11, the control unit 33 acquires, as the charge-discharge history information, the highest voltage value in the charge-discharge cycle in which the discharge end voltage is acquired. An order of Steps S45 and S46 may be reversed.

In Step S47, the control unit 33 compares the charge-discharge history information with the charge suspension condition.

When the charge-discharge history information does not satisfy the discharge suspension condition, the control unit 33 acquires a first voltage representing the highest voltage value in a first charge-discharge cycle in which the discharge end voltage is acquired (Step S49).

In Step S50, the control unit 33 sets a second voltage representing a highest voltage value in a second charge-discharge cycle representing a charge-discharge cycle following the first charge-discharge cycle to a voltage lower than the first voltage.

In Step S51, the control unit 33 instructs the discharge unit 32 to charge the battery module 20 up to the second voltage. The charge-discharge unit 32 connects the battery module 20 and an electric power supply source, and charges the battery module 20. When a voltage measured by the measurement unit 31 reaches the second voltage, the charge-discharge unit 32 interrupts the connection between the battery module 20 and the electric power supply source.

In Step S52, the control unit 33 holds the second voltage as a first voltage. In a subsequent charge-discharge cycle, the battery module 20 can be charged up to the updated first voltage. Steps from Step S40 to Step S52 are thereafter repeated until a discharge end voltage becomes lower than or equal to the reference voltage, or the charge suspension condition is satisfied.

For example, it is assumed that a discharge end voltage in the charge-discharge cycle from t0 to t4 is acquired in the example illustrated in FIG. 11. In this case, the highest voltage value V1 in the charge-discharge cycle from t0 to t4 is acquired as charge-discharge history information. Further, it is assumed that a charge suspension condition is “suspend charging when the highest voltage value in a charge-discharge cycle is lower than or equal to V11.” In this case, the control unit 33 sets a highest voltage value in the charge-discharge cycle from t4 to t8 following the charge-discharge cycle from t0 to t4 to V10 being lower than V1. The control unit 33 instructs the charge-discharge unit 32 to charge the battery module 20 up to the voltage V10. The charge-discharge unit 32 charges the battery module 20 up to the voltage V10 in the charge-discharge cycle from t4 to t8. Similarly, a discharge end voltage in the charge-discharge cycle from t8 to t12 is higher than the reference voltage, and, at the same time, the highest voltage value V10 does not satisfy the charge suspension condition. Accordingly, the operation in Steps S40 to S52 is performed also in the charge-discharge cycle from t8 to t12. The control unit 33 controls a second voltage V11 being lower than the updated first voltage V10 to be the highest voltage value in the charge-discharge cycle from t8 to t12.

On the other hand, when the charge-discharge history information satisfies the discharge suspension condition, the control unit 33 proceeds to Step S48. In Step S48, the control unit 33 instructs suspension of charging of the battery module 20. The control unit 33 suspends charging until a discharge end voltage becomes lower than or equal to the reference voltage. It is assumed that the control unit 33 acquires from outside a charge instruction instructing charging of the battery module 20 in a period in which charging is suspended. In this case, the control unit 33 rejects the charge instruction. Additionally, the control unit 33 may transmit information that the charging is suspended to the source of the instruction.

For example, in Step S41, the discharge end voltage in the charge-discharge cycle from t8 to t12 is acquired, and the highest voltage value (V11) in the charge-discharge cycle (from t8 to t12) is acquired as charge-discharge history information. In this case, the acquired highest voltage value V11 satisfies the charge suspension condition, and therefore the control unit 33 suspends charging of the battery module 20 until a discharge end voltage becomes lower than or equal to the reference voltage.

When the discharge end voltage is lower than or equal to the reference voltage, the control unit 33 proceeds to Step S43. The control unit 33 instructs the capacity measurement unit 34 to start capacity measurement (Step S43). The capacity measurement unit 34 acquires a voltage and a current of the battery module 20 from the measurement unit 31 and starts capacity measurement. When charging is suspended in Step S45, the control unit 33 clears the suspension of charging of the battery module.

In Step S44, the control unit 33 instructs the charge-discharge unit 32 to charge the battery module 20 up to a capacity measurement ending voltage representing a voltage at which capacity measurement is ended. The charge-discharge unit 32 connects the battery module 20 and the electric power supply source, and starts charging. Further, the charge-discharge unit 32 converts AC current supplied from the electric power supply source into DC current and supplies the current to the battery module 20. The measurement unit 31 transmits a voltage and a current of the battery module 20 during charging to the control unit 33 and the capacity measurement unit 34. The capacity measurement unit 34 measures a battery capacity of the battery module by use of the acquired current and the acquired voltage of the battery module. The above concludes the operation of the control device 30.

An example of lowering a highest voltage value as charge-discharge cycles are repeated in Steps S49 to S52 has been described above. However, the method of setting a highest voltage value is not limited to the above. A highest voltage value in each charge-discharge cycle may be set every time a charge-discharge cycle is repeated. Alternatively, a determined second voltage may be used in a plurality of charge-discharge cycles. A number of times a highest voltage value is set in charge-discharge cycles may be appropriately changed in accordance with a degree of demand for capacity measurement and a request by a user or an administrator of the electric power storage device 10.

In the description above, charging is suspended when charge-discharge history information indicating a usage history of the electric power storage device 10 satisfies a charge suspension condition indicating a condition for suspending charging of the battery module 20. However, the charge suspension condition may be a condition for not suspending charging of the battery module 20. In this case, charging of the battery module 20 is suspended when the charge suspension condition is not satisfied.

As described above, the present exemplary embodiment is able to provide effects similar to those according to the first to the third exemplary embodiments.

Further, the present exemplary embodiment compares charge-discharge history information with a charge suspension condition when a discharge end voltage is higher than a reference voltage. When the charge-discharge history information satisfies the charge suspension condition, charging of the battery module 20 is suspended until the discharge end voltage becomes lower than or equal to the reference voltage. In other words, the electric power storage device 10 operates in a discharging or waiting state until the discharge end voltage becomes lower than or equal to the reference voltage. Accordingly, charge energy of the electric power storage device 10 does not increase until the discharge end voltage reaches the reference voltage. Consequently, capacity measurement can be more rapidly started. Further, compared with the first to the third exemplary embodiments, a number of periods in which whether or not capacity measurement can be started is determined, and a number of determinations can be reduced.

Further, the present exemplary embodiment determines whether to charge the battery module 20 up to a second voltage being lower than a first voltage in a first charge-discharge cycle or suspend charging of the battery module 20, in accordance with charge-discharge history information indicating a usage history of the electric power storage device 10. The present exemplary embodiment as described above is able to give priority to a regular operating state repeating charging and discharging in an electric power storage device 10 with lower priority for capacity measurement, while giving priority to capacity measurement in an electric power storage device 10 with higher priority for capacity measurement.

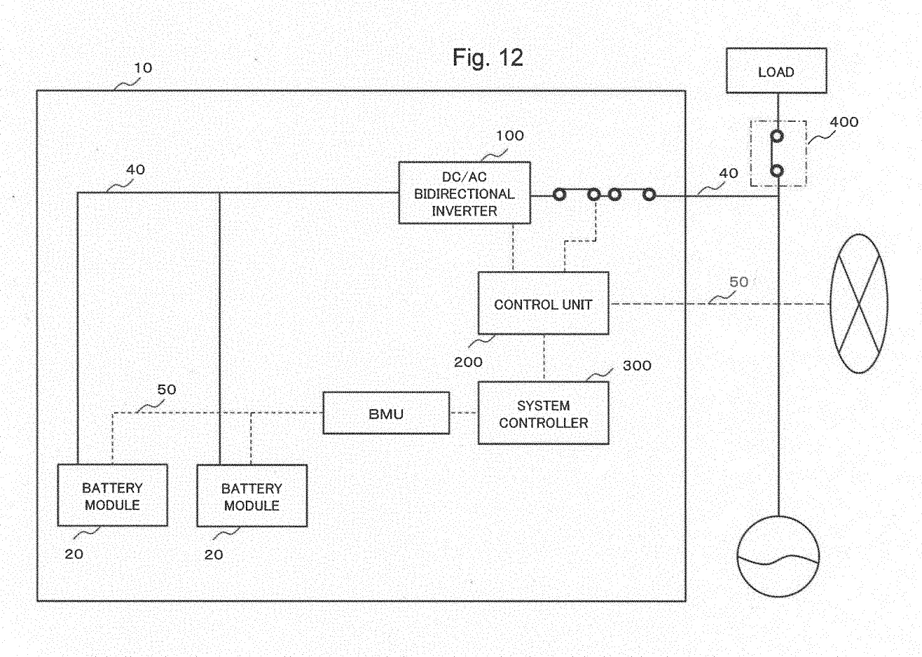

FIG. 12 is a diagram illustrating an example of a configuration of an electric power storage system. The electric power storage system includes an electric power storage device 10, a load, a distribution system, and a network. The electric power storage device 10 is connected to the load and a trunk system through an electric power line 40. Further, the load is connected to the distribution system 40 through the electric power line 40.

The distribution system and the electric power storage device 10 are connected to a distribution board 400. The distribution board 400 includes a branch open circuit for distributing electric power supplied by the distribution system and the electric power storage device 10 to the load. Additionally, a switch may be included for each of the distribution system and the electric power device 10.

The electric power storage device 10 includes a plurality of battery modules 20 storing or releasing electric power, a battery management unit (BMU), a DC/AC bidirectional inverter 100, a control unit 200, and a system controller 300.

The battery module 20 is connected to the BMU through a communication line 50. The BMU is connected to the system controller 300 through the communication line 50.

The BMU prevents anomalies of the battery module 20 such as overcharge, overdischarge, overcurrent, and a temperature anomaly. The BMU is provided by an electronic circuit including a known protective integrated circuit (IC) supporting a secondary battery in the electric power storage device 10, and also including various types of electronic devices. A plurality of the battery modules 20 according to this example are connected to and monitored by the common BMU.

The DC/AC bidirectional inverter 100 converts AC power supplied from the distribution system into DC power that can be stored in the battery module 20. Further, the DC/AC bidirectional inverter 100 converts DC power discharged from the battery module 20 into AC power that can be supplied to the load and the distribution system. The DC/AC bidirectional inverter is connected to the distribution system and the load through the electric power line 40. Further, DC/AC bidirectional inverter 100 is connected to the control unit 200 (to be described later) through the communication line 50. The DC/AC bidirectional inverter 100 is composed of known components such as a DC/AC inverter circuit, an AC/DC converter, a DC/DC converter, and a relay (switch) for switching circuits.

The control unit 200 controls an operation of the DC/AC bidirectional inverter 100 in accordance with an instruction from the system controller 300 (to be described later). Further, the control unit 200 also monitors an operation of the BMU. The control unit 200 is connected to the system controller 300 through the communication line 50. Accordingly, the control unit 200 is able to transmit information to the system controller 300 and receive information from the system controller 300. Further, the control unit 200 is connected to the network through the communication line 50 and transmits or receives information. The control unit 200 includes a known current-power conversion circuit receiving a current value detected by the BMU and converting the current value into an electric power value. Further, the control unit 200 includes a known logic circuit outputting a control signal for switching operations of the BMU, the DC/AC bidirectional inverter, or the like, in accordance with an instruction from the system controller 300.

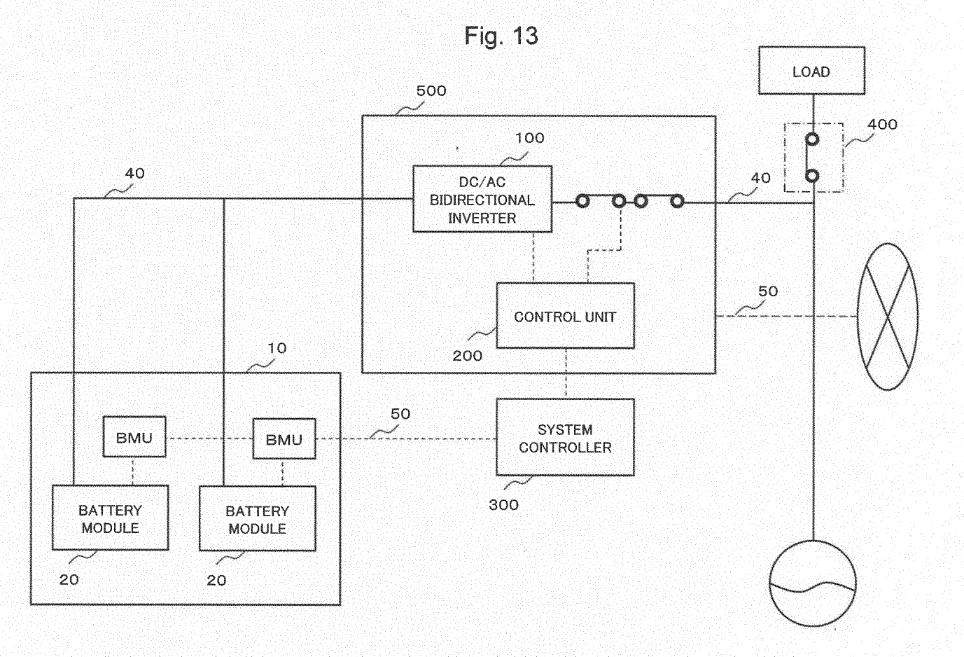

The system controller 300 controls an entire operation of the electric power storage device 10 including the BMU, the DC/AC bidirectional inverter 100, and the control unit 200. The system controller 300 includes a central processing unit (CPU) and various types of logic circuits. Further, the system controller 300 is connected to the BMU and the control unit 200 through the communication line 50. The system controller 300 performs processing in accordance with a program stored in a storage medium. FIG. 13 is a diagram illustrating a modified example of a configuration of the electric power storage system. An electric power storage system according to this modified example includes an electric power storage device 10, a power conditioner 500 including a DC/AC bidirectional inverter 100 and a control unit 200, a system controller 300, a load, a distribution system, and a network. The power conditioner 500 and the system controller 300, according to this modified example, are devices physically separated from the electric power storage device 10.

The electric power storage device 10 according to this modified example includes a plurality of battery modules 20 and a plurality of BMUs. Each BMU monitors or protects a corresponding battery module 20. The electric power storage device 10 is connected to the power conditioner 500 through an electric power line 40. The electric power storage device 10 supplies electric power to the distribution system through the power conditioner 500. Further, the electric power storage device 10 is supplied with electric power from the distribution system through the power conditioner 500.

The power conditioner 500 includes the DC/AC bidirectional inverter 100 and the control unit 200.

The system controller 300 is connected to a plurality of the BMUs in the electric power storage device 10 through a communication line 50. Further, the system controller 300 is connected to the power conditioner 500 through the communication line 50. The system controller 300 may be connected to a plurality of electric power storage devices 10 and control each electric power storage device 10.

While the present invention has been described above with reference to the exemplary embodiments, the present invention is not limited to the aforementioned exemplary embodiments. Various changes and modifications that can be understood by a person skilled in the art may be made to the configurations and details of the present invention, within the scope of the present invention.

The present invention is based on Japanese Patent Application No. 2014-197744 filed on Sep. 29, 2014. The description, claims, and drawings of Japanese Patent Application No 2014-197744 are incorporated herein in its entirety by reference.

### REFERENCE SIGNS LIST

10 Electric power storage device

20 Battery module

30 Control device

31 Measurement unit

32 Charge-discharge unit

33 Control unit

34 Capacity measurement unit

40 Electric power line

50 Communication line

1. A control device for controlling an operation of a plurality of charge-discharge cycles, the charge-discharge cycle including charging of a secondary battery and discharging following the charging, the control device is configured to:
acquire
a first voltage representing a highest voltage value in a first of the charge-discharge cycle,
a discharge end voltage representing a voltage in a period from an end of discharging to a next start of charging in the first charge-discharge cycle, and
a reference voltage representing a voltage at which capacity measurement of a secondary battery is started; and,
lower a second voltage below the first voltage in cases where the discharge end voltage is higher than the reference voltage, the second voltage representing a highest voltage value in a second charge-discharge cycle following the first charge-discharge cycle.

2. The control device according to claim 1, wherein the control device is configured to
acquire at least one of highest voltage values in a plurality of the charge-discharge cycles as the first voltage, and
lower the second voltage below the first voltage.

3. The control device according to claim 1, wherein the control device is configured to
acquire charge-discharge history information indicating a usage history of the secondary battery, and a charge suspension condition indicating a condition for suspending charging of the secondary battery, and
suspend charging of the secondary battery when the charge-discharge history information satisfies the charge suspension condition.

4. The control device according to claim 1, wherein the control device is configured to
acquire charge-discharge history information indicating a usage history of the secondary battery, and a charge suspension condition indicating a condition for suspending charging of the secondary battery, and
lower the second voltage below the first voltage in cases where the discharge end voltage is higher than the reference voltage, and the charge-discharge history information does not satisfy the charge suspension condition.

5. The control device according to any one of claim 1, wherein the control device configured to,
in cases where the discharge end voltage is lower than or equal to the reference voltage,
charge the secondary battery up to a capacity measurement ending voltage representing a voltage at which capacity measurement is ended, and
measure a battery capacity of the secondary battery.

6. An electric power storage device comprising:
a battery module including one or more secondary batteries, and
a control device configured to acquire
a first voltage representing a highest voltage value in a first of the charge-discharge cycle,
a discharge end voltage representing a voltage in a period from an end of discharging to a next start of charging in the first charge-discharge cycle, and
a reference voltage representing a voltage at which capacity measurement of a secondary battery is started; and,
charge the battery module up to a second voltage in cases where the discharge end voltage is higher than the reference voltage, the second voltage being lower than the first voltage.

7. The electric power storage device according to claim 6, further comprising a display unit configured to display information received from the control device, wherein
the control device is configured to transmits the second voltage to the display unit.

8. An electric power storage system comprising:
an electric power storage device configured to indicate a battery module including one or more secondary batteries, and a control device controlling charging and discharging of the battery module, and
a load and an electric power supply source connected to the electric power storage device, wherein
the control device configured to
acquire
a first voltage representing a highest voltage value in a first charge-discharge cycle including charging and discharging following the charging,
a discharge end voltage representing a voltage in a period other than charging and discharging in the first charge-discharge cycle, and at the same time a voltage in a period from an end of discharging to a next start of discharging, and
a reference voltage representing a voltage at which capacity measurement is started, and
charge the battery module up to a second voltage lower than the first voltage when the discharge end voltage is higher than the reference voltage.

9. (canceled)

10. A method for controlling an electric power storage device that includes a battery module including one or more secondary batteries, the method comprising:
acquiring a first voltage representing a highest voltage value in a first charge-discharge cycle including charging and discharging following the charging;
acquiring a discharge end voltage representing a voltage in a period other than charging and discharging in the first charge-discharge cycle, and at the same time a voltage in a period from an end of discharging to a next start of discharging;
acquiring a reference voltage representing a voltage at which capacity measurement is started; and,
lowering a second voltage below the first voltage in cases where the discharge end voltage is higher than the reference voltage, the second voltage representing a highest voltage value in a second charge-discharge cycle following the first charge-discharge cycle.

11. A non-transitory computer-readable medium storing a control program for controlling an operation of a plurality of charge-discharge cycles including charging of a secondary battery and discharging following the charging, the control program causing a computer to perform:
processing of acquiring a first voltage representing a highest voltage value in a first of the charge-discharge cycles; and
processing of lowering a second voltage below the first voltage in cases where the discharge end voltage is higher than the reference voltage, the second voltage representing a highest voltage value in a second charge-discharge cycle following the first charge-discharge cycle.

12. (canceled)
